(19) United States
(12) Patent Application Publication
(10) Pub. No.: US 2026/0231410 A1
(43) Pub. Date: Aug. 6, 2026

(54) Non-Volatile Memory Cell and Memory

(71) Applicant: Chengdu Analog Circuit Technology Inc., Chengdu (CN)

(72) Inventors: Jianjun Xiang, Chengdu (CN); Zhongbo He, Chengdu (CN); Yulong Wang, Chengdu (CN); Feilong Chen, Chengdu (CN)

(21) Appl. No.: 19/392,737

(22) Filed: Nov. 18, 2025

(30) Foreign Application Priority Data
Feb. 5, 2025 (CN) 202510128783.X

(51) Int. Cl. H10B 41/70

(52) U.S. Cl. CPC H10B 41/70

(57) ABSTRACT

A non-volatile memory cell includes a first well and a second well of different types adjacently disposed; a first transistor disposed in the first well, the first transistor including a floating gate and a gate-oxide of the floating gate; and a capacitor disposed in the second well, the capacitor including a coupling region disposed in the second well. The floating gate and the gate oxide extend from the first well to the second well, forming the gate and a gate-oxide of the capacitor. The floating gate includes two electrically different portions, and a PN junction is formed at a junction of the two portions, and is close to an end of the floating gate. The distance between the PN junction and the end of the floating gate is less than 150 nm.

### CROSS REFERENCE TO RELATED APPLICATIONS

This application claims priority to and benefits from Chinese Application No. 202510128783.X, filed on February 5, 2025, the entire contents of which are incorporated herein by reference.

### TECHNICAL FIELD

The disclosure relates to non-volatile memory cell and memory. More particularly, the disclosure relates to a multi-time electrically programmable and erasable non-volatile memory cell and a memory thereof.

### BACKGROUND

As semiconductor manufacturing processes continue to scale down, the number of transistors integrated on a silicon-chip continues to increase. Integrating the whole system on a single chip becomes a possibility for many applications. Multiple systems contain many separate components, such as electrically erasable programmable read-only memory (EEPROM), dynamic random access memory (DRAM), and FLASH, which are generally fabricated using specialized processes.

### SUMMARY

A first aspect of the disclosure relates to a non-volatile memory cell, including a first well and a second well of different types adjacently disposed; a first transistor disposed in the first well, the first transistor including a floating gate and a gate-oxide of the floating gate; a capacitor disposed in the second well, and the capacitor including a coupling region disposed in the second well, in which the floating gate and the gate-oxide extend from the first well to the second well forming the gate and the gate-oxide of the capacitor.

A second aspect of the disclosure provides a non-volatile memory, including at least one non-volatile memory cell formed on a substrate, in which the non-volatile memory cell includes a first well and a second well of different types adjacently disposed; a first transistor disposed in the first well, the first transistor including a floating gate and a gate-oxide of the floating gate; and a capacitor disposed in the second well, the capacitor including a coupling region disposed in the second well, in which the floating gate and the gate-oxide extend from the first well to the second well forming the gate and the gate-oxide of the capacitor, the substrate includes a deep well, the first well and the second well of the non-volatile memory cell are disposed in the deep well.

### BRIEF DESCRIPTION OF THE DRAWINGS

The accompanying drawings are used for better understanding of the technical solution of the disclosure, and do not constitute a limitation to the disclosure.

FIG. 1 illustrates a top view of a non-volatile memory cell according to an embodiment of the disclosure.

FIG. 2 illustrates a cross-sectional view of a memory cell in the embodiment illustrated in FIG. 1 along the section line A-A.

FIG. 3 illustrates a cross-sectional view of a memory cell in the embodiment illustrated in FIG. 1 along the section line B-B.

FIG. 4 illustrates a cross-sectional view of a memory cell in the embodiment illustrated in FIG. 1 along the section line C-C.

FIG. 5 illustrates a partial top view of a memory cell illustrated in FIG. 1 including a floating gate.

FIG. 6 illustrates a partial top view of a floating gate of a memory cell in priori art having a structure similar to that of the memory cell illustrated in FIG. 1.

FIG. 7 illustrates volt-ampere characteristic curves of floating gates of the two memory cells illustrated in FIGS. 5-6.

FIG. 8 illustrates a step of forming an active region of a memory cell illustrated in FIG. 1.

FIG. 9 illustrates another step of forming an active region of a memory cell illustrated in FIG. 1.

FIG. 10 illustrates still another step of forming an active region of a memory cell illustrated in FIG. 1.

The same numbers in the drawings indicate the same or similar elements.

### DETAILED DESCRIPTION

The following describes embodiments of the disclosure with reference to the accompanying drawings, which include various details of embodiments of the disclosure to facilitate understanding, and should be regarded as merely exemplary. Therefore, those of ordinary skill in the art should recognize that various changes and modifications can be made to the embodiments described herein without departing from the scope of the disclosure. Likewise, for clarity and conciseness, descriptions of well-known functions and structures are omitted in the following description.

As semiconductor manufacturing processes continue to scale down, the number of transistors integrated on a silicon-chip continues to increase. Integrating the whole system on a single chip becomes a possibility for many applications. However, multiple systems contain many separate components, such as electrically erasable programmable read-only memory (EEPROM), dynamic random access memory (DRAM), and FLASH, which are generally fabricated using specialized processes. These specialized processes may not be compatible with the common logic processes used for manufacturing logic components such as micro-processors and system logics.

In order to integrate these specialized memory component (such as EEPROM, DRAM and FLASH) in the logic process, additional manufacturing processes may need to be added to the existing logic process. The adding process steps will increase the manufacturing cost of the whole chip, including the logic components, which is inconsistent with the chip manufacturers' compression of the manufacturing process to the maximum extent. In view of this, the memory circuits need to be designed to be compatible with the logic process, and especially for chips in which the logic circuits occupy the majority of the chip area, this compatibility becomes more desirable.

For a non-volatile memory (such as the EEPROM and the FLASH), fabricated by the logic process, that is compatible with the logic process, an effective scheme and structure is described in US7983081B2. A deep well is used for isolating the memory cell from a substrate, and the substrate is connected to ground or is 0v in multiple cases. The memory cell includes a metal oxide semiconductor (MOS) transistor and a MOS capacitor. The MOS transistor and the MOS capacitor are respectively fabricated in two different types of wells. The two different types of wells are adjacent and disposed in a deep well. The transistor and the capacitor share a floating gate and a gate-oxide layer underlying the floating gate. The MOS capacitor includes a lightly doped region and an adjacent coupling region located in a well where the MOS capacitor is located. An end of the shared floating gate close to the capacitor partially overlaps with the lightly doped region of the capacitor in the well. The coupling capacitor structure consists of the floating gate partially overlapping the doped region of the capacitor in the well, the underlying gate-oxide and the MOS channel. The coupling region of the capacitor couples a control word line (CWL) to a control gate of the memory cell. The control gate is formed by the channel region of the MOS capacitor. To increase the effectiveness of the coupling gate, the coupling capacitance is made substantially larger than the MOS gate capacitance.

This scheme is compatible with the logic processes, does not require specialized circuits, is simple to fabricate, and has a small memory cell size and excellent performance. However, in this structure, since the MOS transistor and the MOS capacitor share one floating gate, the two ends of the floating gate are adjacent to the active region of the transistor and to the active region of the capacitor with different electrical properties in different wells respectively. In forming an active region, the corresponding dopant ions will penetrate from the side of the floating gate adjacent to the active region, resulting in forming two portions with different electrical properties in the floating gate, and a PN junction is formed at a junction of the two portions, making the potential in the floating gate unstable, thereby affecting the performance, stability and reliability of the memory cell and the memory during operation.

Therefore, a new non-volatile memory cell and memory thereof that may solve the above problems are needed.

The non-volatile memory cell and the memory thereof according to the disclosure are multi-times electrically programmable and erasable non-volatile memory cell and the memory thereof.

In the non-volatile memory cell according to the disclosure, the first transistor includes a floating gate and an underlying gate-oxide. In an embodiment, the floating gate is a polysilicon gate. The floating gate and its gate-oxide extend from a first well to a second well, forming a gate and its gate-oxide for a capacitor. The floating gate slightly overlaps an edge portion of an active region (a coupling region of the capacitor) in the second well. The coupling region of the capacitor connects a control word line (WL) to a control gate of the memory cell. The control gate is formed by a channel region of the capacitor. Thus, the coupling capacitor structure consists of the floating gate slightly overlapping the active region in the second well, the underlying gate-oxide, and a capacitor channel. To improve an effectiveness of the coupling gate, the coupling capacitor is made substantially larger than the capacitance of the first transistor gate.

The programming and erasing of the memory cell are performed in the first transistor. The programming is performed by hot channel electron (or hole) of the first transistor tunneling to the floating gate. The erasing operation is performed based on Fowler-Nordheim tunneling mechanism, which tunnels electrons (or holes) from the floating gate to the channel. The tunneling oxide used for both programming and erasing operations is the gate-oxide over the channel region of the first transistor. During the operations, the potential applied to the coupling region of the capacitor by the CWL is coupled to the floating gate through the capacitor, so that the floating gate obtains the required potential.

In a non-volatile memory cell of the prior art with a structure similar to that of the disclosure, the first transistor and the capacitor located in different types of wells share a floating gate, and the source and the drain of the first transistor have different electrical properties from the coupling region of the capacitor. When respective dopant ions are injected into the active regions from both sides of the floating gate to form the source and drain of the transistor and the coupling region of the capacitor, the sides of the floating gate adjacent to the active regions will be infiltrated by the corresponding dopant ions, resulting in forming two portions with different electrical properties in the floating gate, and a PN junction is formed at a junction of the two portions (approximately in the middle of the floating gate). In an example, in the case where the source and drain of the first transistor and the coupling region of the capacitor contain highly doped regions, it needs to repeatedly inject the respective dopant ions into the predetermined active regions from both sides of the floating gate during the fabrication, such that more respective dopant ions are infiltrated into the sides of the floating gate, and a larger PN junction is formed in the floating gate. When the memory cell is working, a potential is applied to the coupling region of the capacitor, and a coupling capacitance is larger than the gate capacitance of the first transistor, such that the applied potential is coupled to the floating gate through the capacitor, and the floating gate obtains the required potential. The existence of the PN junction in the middle of the floating gate makes the major portion of the floating gate no longer a net electrically P-type or N-type gate, and there is an internal electric field in the PN junction in the floating gate, which causes the coupling potential obtained by the floating gate and its uniformity to decrease, and the stability of the coupling potential also to decrease.

The disclosure moves the position of the junction (i.e. the PN junction) of two different electrical properties in the floating gate from the middle of the floating gate to an end of the floating gate, such that the major portion of the floating gate presents a P or N net electrical property, thereby weakening or eliminating the adverse effects of the PN junction on the floating gate. The PN junction may be located at an end of the floating gate adjacent to the capacitor side (also called capacitor-side end) or to an end adjacent to the first transistor side (also called first transistor-side end). In an embodiment, the PN junction is adjacent to the capacitor-side end.

The PN junction in the floating gate according to the disclosure is adjacent to one end of the floating gate, which may be achieved by the following.

The source and drain of the first transistor and the coupling region of the capacitor are respectively disposed in the active regions of their respective wells, and there is a thick field oxide (FOX) isolation region between the two active regions for isolation. The thick field oxide isolation region is located at a junction of the two wells. In the process of manufacturing the memory cell, when forming the active region of the capacitor and the active region of the first transistor, the border of the active region of the capacitor adjacent to the isolation region is made close to the capacitor-side end of the floating gate, or the border of the active region of the first transistor adjacent to the isolation region is made close to the first transistor-side end of the floating gate, and the corresponding ions are injected to the predetermined regions accordingly to realize that the PN junction in the floating gate is close to one end of the floating gate.

The non-volatile memory cell according to the disclosure includes a first well and a second well of different types adjacently disposed. A first transistor and a capacitor are respectively disposed in the first well and the second well. The first transistor and the capacitor share a floating gate and a gate-oxide thereof. The floating gate includes two portions with different electrical properties. A junction (i.e., a PN junction) between the two portions is close to an end of the floating gate, and a distance between the junction (PN junction) and the end of the floating gate is greater than 0 and less than 150 nanometers (nm). In an embodiment, the distance ranges from 2 nm to 130 nm. In an embodiment, the distance ranges from 5 nm to 100 nm. In an embodiment, the distance ranges from 10 nm to 70 nm.

The distance between the PN junction in the floating gate and the end of the floating gate refers to a distance along a length direction of the floating gate. The length direction of the floating gate is a direction from the first transistor-side end to the capacitor-side end of the floating gate, which is perpendicular to a length direction of the first transistor (a direction from the source to the drain of the first transistor).

In the disclosure, the length of the floating gate, that is, the length from the first transistor-side end to the capacitor-side end of the floating gate, is 1000 nm to 6000 nm.

The PN junction in the floating gate may be close to either of the two ends of the floating gate. In an embodiment, the PN junction is close to the capacitor-side end of the floating gate, that is, the end of the floating gate close to the capacitor and away from the first transistor.

A first embodiment of the disclosure provides a memory cell. The PN junction in the floating gate is close to the capacitor-side end of the floating gate. In an embodiment, the source and the drain of the first transistor each contain a highly doped region, or the coupling region of the capacitor is a lightly doped region. This may further enhance the net electrical property of a major portion of the floating gate, and at this time, the net electrical property of the major portion of the floating gate is the same as the type of highly doped ions in the source and the drain of the first transistor. In an embodiment, the source and the drain of the first transistor each contain a highly doped region, and the coupling region of the capacitor is a lightly doped region.

In an embodiment, the first well and the second well are respectively an N-well and a P-well. The first transistor is a positive channel metal oxide semiconductor (PMOS) transistor. The source and the drain each include a P+ highly doped region. The capacitor is an N-metal-oxide-semiconductor (NMOS) capacitor, and its coupling region in the second well is an N-type lightly doped region. In this case, the PN junction in the floating gate is close to the end of the floating gate close to the capacitor, and the major portion of the floating gate presents the P+ net electrical property. The working mode of the memory cell is as follows. When the memory cell is programmed, a positive potential is applied to the N coupling region of the NMOS capacitor, and the floating gate whose major portion presents the P+ net electrical property is positively biased through the capacitive coupling. Opposite potentials are applied respectively to the source and the drain of the PMOS transistor, such that a strong lateral electric field is formed between the source and the drain. Holes are accelerated along the channel of the first transistor in the strong electric field. Collision ionization occurs in a depletion region of the drain. The generated hot electrons are attracted by the positively biased floating gate and injected into the floating gate. The electrons are injected into the floating gate, resulting in a decrease in the threshold voltage of the PMOS transistor, making it easy to turn on, and causing the read current during the read operation to increase. When the memory cell is erased, a negative potential is applied to the N coupling region of the NMOS capacitor, the floating gate whose major portion presents the P+ net electrical property obtains the required negative potential through the capacitive coupling and an absolute value of the negative potential is smaller than the value of the potential applied to the coupling region of the capacitor. The same positive potential is applied to the source and the drain of the PMOS transistor, thereby forming a high electric field between both sides of the gate-oxide layer of the first transistor, which is sufficient to cause the electrons trapped in the floating gate to tunnel into the channel of the PMOS transistor. The electrons are removed from the floating gate, causing the threshold voltage of the first transistor to increase, making it difficult to turn on, and causing the read current to decrease.

In the embodiment, the first well and the second well may also be a P-well and an N-well respectively. The first transistor is an NMOS transistor. The source and the drain each include an N+ highly doped region. The capacitor is a PMOS capacitor, and its coupling region in the second well is a P-type lightly doped region. In such a case, the PN junction in the floating gate is still close to the capacitor-side end of the floating gate, and at this time, the major portion of the floating gate presents the N+ net electrical property. The working mode of the memory cell is different from the above. When the memory cell is programmed, a negative potential is applied to the P coupling region of the PMOS capacitor, and the floating gate whose major portion presents the N+ net electrical property is negatively biased through the capacitive coupling. Opposite potentials are applied respectively to the source and the drain of the NMOS transistor, such that a strong lateral electric field is formed between the source and the drain. The electrons are accelerated along the channel of the first transistor in the strong electric field. Collision ionization occurs in the depletion region of a terminal (such as the source), and the generated holes are attracted by the negatively biased floating gate and injected into the floating gate. The holes are injected into the floating gate, causing the threshold voltage of the NMOS transistor to decrease, making it easy to turn on, and causing the read current during the read operation to increase. When the memory cell is erased, a positive potential is applied to the P coupling region of the PMOS capacitor, the floating gate whose major portion presents the N+ net electrical property obtains the required positive potential through the capacitive coupling and an absolute value of the positive potential is smaller than a value of the potential applied to the coupling region of the capacitor. The same negative potential is applied to the source and the drain of the NMOS transistor, thereby forming a high electric field between both sides of the gate-oxide layer of the first transistor, which is sufficient to cause the holes trapped in the floating gate to tunnel into the channel of the NMOS transistor. The holes are removed from the floating gate, causing the threshold voltage of the first transistor to increase, making it difficult to turn on, and causing the read current to decrease.

In a second embodiment of the memory cell of the disclosure, the PN junction in the floating gate may also be close to the transistor-side end of the floating gate, that is, an end of the floating gate close to the first transistor and away from the capacitor. In this case, the source and the drain of the first transistor are lightly doped regions, or the coupling region of the capacitor includes a highly doped region. This may further enhance the net electrical property of the major portion of the floating gate, and at the same time, the net electrical property of the major portion of the floating gate is the same type as the highly doped ions of the coupling region of the capacitor. In an embodiment, the source and the drain of the first transistor are lightly doped regions, and the coupling region of the capacitor includes a highly doped region.

In the embodiment, the first well and the second well are N-well and P-well respectively. The first transistor is a PMOS transistor. The source and the drain are P lightly doped regions. The capacitor is an NMOS capacitor. The coupling region is an N+ highly doped region. In this case, the PN junction in the floating gate is close to a first transistor-side end of the floating gate, and the major portion of the floating gate presents the N+ net electrical property. The structure of this memory cell is similar to the first memory cell in the first embodiment described above (that is, the first well and the second well are N-well and P-well respectively, the first transistor is a PMOS transistor, the source and the drain include P+ highly doped regions, the capacitor is an NMOS capacitor, and its coupling region is an N lightly doped region), except that the position of the PN junction in the floating gate is different and the net electrical property of the major portion of the floating gate is different. That is, the difference includes that the PN junction is adjacent to different ends of the floating gate respectively, and one major portion of the floating gate presents the N+ net electrical property and the other presents the P+ net electrical property. Compared with the memory cell in the first embodiment, the distance between the PN junction in the floating gate and the end of the floating gate (i.e., the first transistor-side end) in this embodiment cannot be too small, otherwise it will cause the active region of the first transistor to be too narrow, which will affect the performance of the first transistor. In this case, the distance between the PN junction in the floating gate and the transistor-side end of the floating gate ranges from 30 nm to 150 nm. In an embodiment, the distance ranges from 50 nm to130 nm. This embodiment may partially weaken the adverse effect of the PN junction on the floating gate, but the effect is not as good as that of the first embodiment. In addition, the working mode of this embodiment is similar to the memory cell having a first structure in the first embodiment above, although one major portion of the floating gate presents the N+ net electrical property and the other presents the P+ net electrical property, and specific values of the potential applied to the coupling region of the capacitor during programming or erasing operations is slightly different, but the working principles and modes of the two are similar.

In the embodiment, the first well and the second well may also be a P-well and an N-well respectively. The first transistor is an NMOS transistor. The source and the drain include N lightly doped regions. The capacitor is a PMOS capacitor, and its coupling region in the second well is a P+ highly doped region. In this case, the PN junction in the floating gate is still close to the first transistor-side end of the floating gate, and the major portion of the floating gate body presents the P+ net electrical property. The structure of this embodiment is similar to the memory cell having a second structure in the first embodiment mentioned above (that is, the first well and the second well are P-well and N-well respectively, the first transistor is an NMOS transistor, the source and the drain include an N+ highly doped regions, the capacitor is a PMOS capacitor, and the coupling region is a P lightly doped region). The difference is that the positions of the PN junction in the floating gate of the two are different (that is, the PN junction is close to different ends of the floating gate respectively), and one major portion of the floating gate presents the P+ net electrical property and the other presents the N+ net electrical property. Compared with the memory cell with a similar structure in the first embodiment, the distance between the PN junction in the floating gate and the first transistor-side end of the floating gate in this embodiment cannot be too small, otherwise it will cause the active region of the first transistor to be too narrow, which will affect the performance of the first transistor. In this case, the distance between the PN junction in the floating gate and the first transistor-side end of the floating gate is from 30 nm to 150 nm. In an embodiment, the distance ranges from 50 nm to 130 nm. This embodiment may partially weaken the adverse effect of the PN junction on the floating gate, but the effect is not as good as the first embodiment. In addition, the working mode of this embodiment is similar to the first memory cell in the first embodiment above, although one major portion of the floating gate presents the P+ net electrical property and the other presents the N+ net electrical property, and specific values of the potential applied to the coupling region of the capacitor during programming or erasing operations is slightly different, but the working principles and modes of the two are similar.

The non-volatile memory cell according to the disclosure may further include a second transistor, which is of the same type as the first transistor, located in the first well and connected in series with the first transistor. The second transistor serves as a gate transistor for the programmable first transistor to minimize the programming disturbance problem.

The disclosure also provides a non-volatile memory including at least one of the above-mentioned non-volatile memory cells fabricated on a substrate. There is a deep well in the substrate, and the first well and the second well are disposed in the deep well. In an embodiment, the substrate is a P-type substrate, and the deep well is a deep N-well. In an embodiment, the first well and the second well are respectively an N-well and a P-well, the first transistor is a PMOS transistor, the capacitor is an NMOS capacitor, and the coupling region of the capacitor in the second well is an N-coupling region. In an embodiment, the memory is a multi-time programmable and erasable non-volatile memory.

The memory cell and the memory according to the disclosure may be fabricated using conventional methods in the prior art. Only when forming the active regions of the capacitor and of the first transistor, the border of the active region of the capacitor adjacent to the isolation region is close to the capacitor-side end of the floating gate, or the border of the active region of the first transistor adjacent to the isolation region is close to the first transistor-side end of the floating gate, and corresponding dopant ions are injected to the predetermined active regions to realize that the PN junction in the floating gate is close to the capacitor-side end of the floating gate or to the first transistor-side end of the floating gate. In the case where the border of the active region of the capacitor adjacent to the isolation region is close to the capacitor-side end of the floating gate, if the border of the isolation region adjacent to the capacitor moves, along with the above-mentioned border of the active region of the capacitor, toward the capacitor-side end of the floating gate, then the size of the coupling region of the capacitor along the length direction of the floating gate will be narrowed, resulting in a decrease in the capacitor coupling rate. In order not to reduce the coupling rate of the capacitor, in an embodiment, the border of the isolation region adjacent to the capacitor does not move with the above-mentioned border of the active region of the capacitor or is not close to the capacitor-side end of the floating gate, but an ion doping region of the same type as the active region (the source and the drain) of the first transistor is added in parallel therewith between the isolation region and the active region of the capacitor. This may ensure that the effective area and coupling rate of the capacitor do not decrease, and may further enhance the net electrical property of the major portion of the floating gate. At this time, the net electrical property of the major portion of the floating gate is the same as the electrical property of the source and the drain of the first transistor.

In the memory cell according to the disclosure, the PN junction in the floating gate is close to the end of the floating gate, which may weaken or eliminate the adverse effects of the PN junction on the floating gate, increase the coupling potential obtained by the floating gate, improve the uniformity and stability of the coupling potential obtained by the floating gate, reduce the discreteness of the coupling, and improve the average value of the threshold voltage of the first transistor after erasure, all of which help to improve the stability and reliability of the memory.

The memory cell and the memory thereof according to the disclosure are described in detail below with reference to a specific embodiment. Obviously, various adjustments and changes may be made to the embodiment without departing from the purpose and scope of the disclosure.

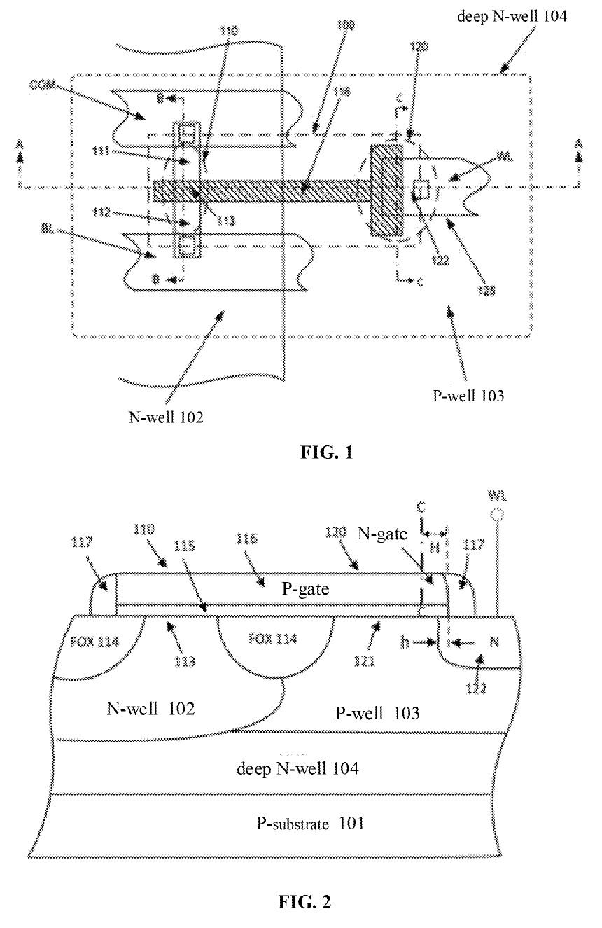

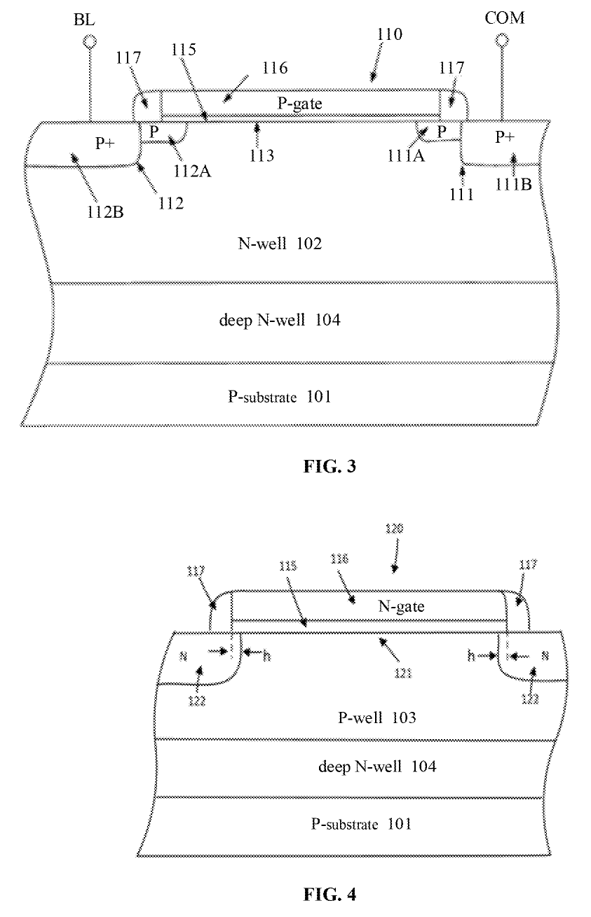

FIG. 1 illustrates a top view of the non-volatile memory cell 100 according to the disclosure. FIGS. 2-4 illustrate cross-sectional views along the section lines A-A, B-B, and C-C in FIG. 1, respectively. The section line C-C in the figure is a boundary line between two electrically different portions in the floating gate 116, and is also a position line of the PN junction, which is close to the capacitor 120-side end of the floating gate 116. The left and right sides of the C-C line are the P-type and N-type electrical portions of the floating gate 116, respectively, which are called the P gate and the N gate.

In this embodiment, the non-volatile memory cell 100 is fabricated in a P-type silicon substrate 101. A deep N-well 104 is disposed in the P-substrate 101, and the deep N-well 104 electrically isolates the memory cell 100 from the substrate 101. The N-well 102 and the P-well 103 are adjacent to each other and are disposed in the deep N-well 104. A first transistor 110 (a PMOS readout transistor in this embodiment) is disposed in the N-well 102, and a capacitor 120 (an NMOS capacitor in this embodiment of the disclosure) is disposed in the P-well 103. The first transistor 110 includes a P-type drain 112 and a P-type source 111. The drain 112 includes a lightly doped region 112A of the drain and a highly doped P+ contact region 112B of the drain. The source 111 includes a lightly doped region 111A of the source and a highly doped P+ contact region 111B of the source.

The source 111 is connected to a common line (COM), and the drain 112 is connected to a bit line (BL). The first transistor 110 is surrounded by a shallow trench filled with a thick field oxide 114 (FOX). A channel 113 region is between the source 111 and the drain 112. The thickness of the gate-oxide 115 overlying the channel 113 is 7 nm. A conductively doped polysilicon gate is placed on top of the gate oxide 115 to form the floating gate 116 of the first transistor 110.

The floating gate 116 and the gate-oxide 115 extend to the P-well 103, forming the upper plate and the dielectric of the capacitor 120. In the P-well 103, the three borders of the N-gate portion of the floating gate 116 adjacent to the active region 122 of the capacitor all slightly overlap with the edge portion of the active region 122 of the capacitor (with the overlap width being h). The active region 122 of the capacitor is also the coupling region of the capacitor 120, which may also be called a charge injection element, and is an N lightly doped region. The gate capacitance value of the capacitor 120 is almost 2.5 times the gate capacitance value of the first transistor 110.

The charge injection element is connected to a word line (WL), which is also connected to the P-well 103 through a P+ contact region (not shown). During storage operation, the WL is used for controlling the voltage of the floating gate 116. During operation, when the potential of the floating gate 116 is greater than that of WL, the voltage difference is greater than the threshold voltage of the capacitor 120, the channel region 121 of the capacitor below the floating gate 116 in the P-well 103 region is inverted, and the electrons emitted by the charge injection element form an electron inversion layer in the channel region 121 of the capacitor, such that the channel region 121 of the capacitor forms the lower plate of the capacitor 120. The lower plate is connected to the WL through the charge injection element.

The floating gate 116 is surrounded by a sidewall isolation 117, which is generally formed of silicon nitride or silicon oxide. When forming the P+ region, the sidewall isolation 117 prevents the P+ implant from entering the lightly doped P region.

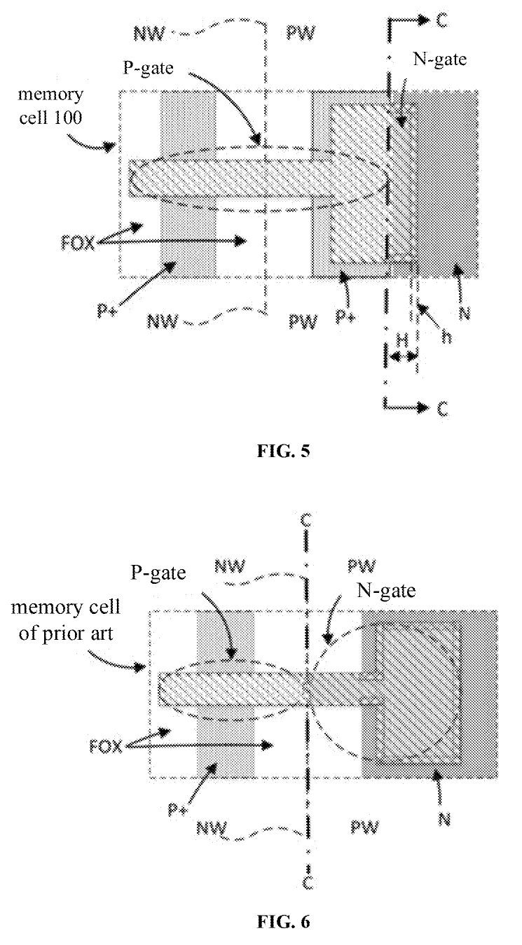

FIG. 5 illustrates a partial top view of the memory cell 100 illustrated in FIG. 1 including the floating gate 116. FIG. 6 illustrates a partial top view of a memory cell having a structure similar to the memory cell 100 in the prior art including the floating gate.

Compared with the memory cell of the prior art illustrated in FIG. 6, the position of the PN junction in the floating gate 116 of the memory cell 100 according to the disclosure illustrated in FIG. 5 (at the C-C dividing line) is moved from the middle of the floating gate 116 to the end of the floating gate 116 close to the capacitor 120 side, and the distance between the PN junction and the end of the floating gate 116 close to the capacitor 120 side is H. In an embodiment, H is 30 nm. Along the length direction of the floating gate 116, the size of the P-gate portion in the floating gate 116 is much larger than the N-gate portion, such that the major portion of the floating gate 116 presents the P+ net electrical property, which may also be referred to as “approximate P gate”. The P+ highly doped region located in the N-well 102 (NW) is the active region of the first transistor 110, the N lightly doped region located in the P-well 103 (PW) is the coupling region of the capacitor, there is a thick field oxide 114 (FOX) isolation region located at the junction of the two wells, and there is a newly added P+ highly doped region in the P-well 103. The newly added P+ highly doped region is located between the isolation region and the coupling region of the capacitor, which may not only ensure that the effective area and coupling rate of the capacitor 120 do not decrease, but also help to make the major portion of the floating gate 116 present the P+ net electrical property.

It may also be seen from FIG. 5 that in the P-well 103, the three borders between the N-gate portion of the floating gate 116 of the memory cell 100 and the coupling region of the capacitor are slightly overlapped with the edge portion of the N-coupling region of the capacitor 120, and the overlap width is h. This overlap width is conducive to injecting electrons by the coupling region (i.e., the charge injection element) of the capacitor into the channel region 121 of the capacitor during the erase operation, forming a steady-state inversion layer, thereby facilitating the coupling of potential to the floating gate 116.

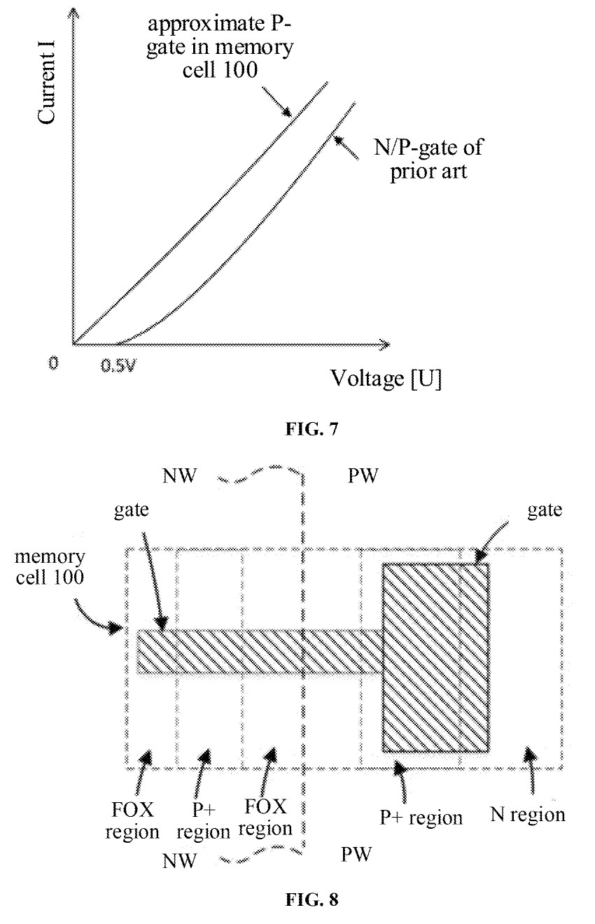

FIG. 7 illustrates volt-ampere characteristic curves of the floating gates of the two memory cells of FIGS. 5-6, that is, the relationship between the current I and the voltage U from the N-gate to the P-gate, which is also a resistance characteristic diagram. As may be seen from FIG. 7, in the floating gate of the memory cell of the prior art, the resistance distribution from the N-gate to the P-gate is uneven, and is significantly higher than the floating gate 116 of the memory cell 100 in the disclosure. This is because there is a PN junction located in the middle of the floating gate between the P-gate and the N-gate in the floating gate of the prior art. The PN junction has an internal electric field, and also causes an initial potential of 0.5V to be displayed on the volt-ampere curve. Only by overcoming this initial potential can current (electrons) move in the floating gate. These will cause the potential obtained by the coupling inside the floating gate to be low and poorly uniform. It may also be seen from FIG. 7 that the resistance in the floating gate 116 of the memory cell 100 in the disclosure is constant and evenly distributed, and its resistance value is significantly lower than the resistance value of the floating gate in the prior art. This is because the PN junction in the floating gate 116 of the memory cell 100 of the disclosure is close to the end, the major portion of the floating gate 116 presents the P+ net electrical property, and the floating gate 116 is approximately a P-type gate. This makes the potential obtained by coupling in the floating gate 116 of the disclosure higher and more uniform, and the coupling degree, as well as the uniformity and stability of the potential obtained by coupling may be improved, which is conducive to uniform erasing during the erasing operation.

The memory cell 100 according to this embodiment is manufactured using a 130 nm logic process. All processing steps required to form the memory cell 100 are existing steps used for forming other on-chip circuits in the logic process, and no additional processing steps are required. Moreover, the manufacturing process of the memory cell 100 is compatible with the standard CMOS process.

The manufacture process of the memory cell 100 according to the disclosure is basically the same as the manufacture process of the memory cell of the prior art illustrated in FIG. 6, and the only difference is that: in forming the active regions of the NMOS capacitor 120 and of the first transistor 110, the border of the active region 122 of the capacitor adjacent to the FOX isolation region is close to the capacitor 120-side end of the floating gate 116, the distance between the border of the active region 122 of the capacitor and the capacitor-side end of the floating gate 116 is 30 nm, a P+ active region is added between the FOX isolation region and the active region 122 of the capacitor in the P-well 103, and respective dopant ions are injected into the predetermined active regions accordingly. FIGS. 8-10 illustrate partial top views of the memory cell 100 including the floating gate 116 in each step of sequentially forming the active regions (the active region of the first transistor 110 and the active region 122 of the capacitor).

As illustrated in FIG. 8, before the step of injecting dopant ions, the gate-oxide 115 and the floating gate 116 are first formed on the N-well 102 and the P-well 103, and a layout is formed based on the positions of the predetermined FOX region (i.e., the isolation region) and the active region (P+ region and N region) illustrated in FIG. 8. In FIG. 8, the P+ region in the N-well 102 is the active region of the first transistor 110, the middle FOX region spans the N-well 102 and the P-well 103, the N region in the P-well 103 is the N active region of the NMOS capacitor 120, and the P+ region in the P-well 103 is the P+ active region added between the middle FOX region and the N active region of the NMOS capacitor 120.

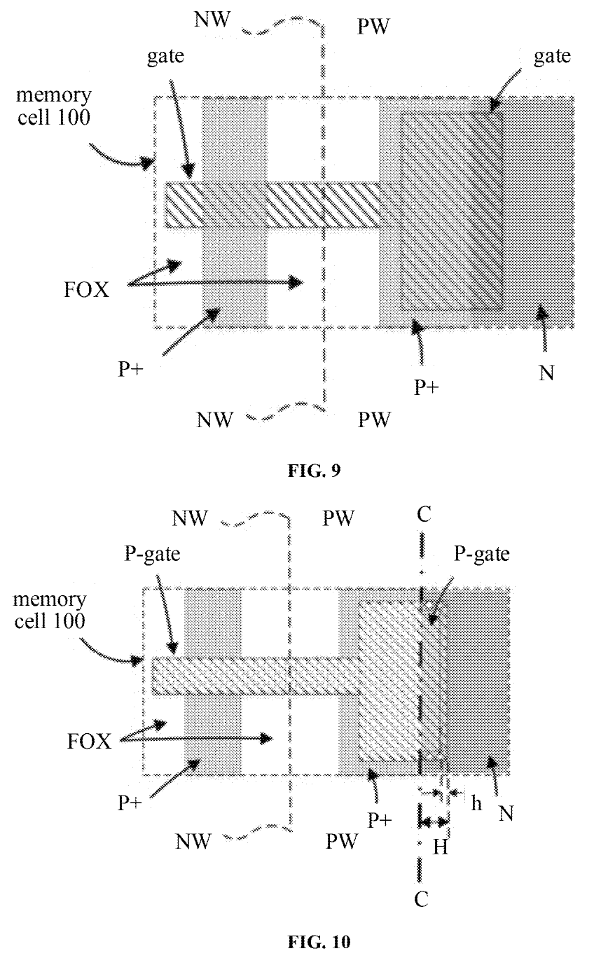

Using a photomask, the region where dopant ions need to be injected is exposed, and a corresponding type of dopant ions are injected into each predetermined active region, as illustrated in FIG. 9, to form the P+ source and the P+ drain of the first transistor 110, the N coupling region of the NMOS capacitor 120, and the P+ active region in the newly added P-well 103.

In the process of injecting dopant ions into the active region, ions injected into the surface of the floating gate 116 from directly above the portion of the floating gate 116 adjacent to the active region rarely penetrate into the floating gate 116, which is determined by the material of the floating gate 116. However, dopant ions injected into the active regions from both sides of the portion of the floating gate 116 adjacent to the active region may penetrate into the floating gate 116 from the sides of the floating gate 116. As illustrated in FIG. 10, the P+ dopant ions injected into the two P+ active regions penetrate into the floating gate 116 from the sides of the floating gate 116 adjacent to the active region, move in the conductor of the floating gate 116, and form the P-gate portion of the floating gate 116. The N dopant ions injected into the N active region penetrate into the floating gate 116 from the side of the floating gate 116, and form the N-gate portion of the floating gate 116. The C-C line is the boundary line between the P-gate and the N-gate in the floating gate 116, and is also the location of the PN junction in the floating gate 116. The distance H between the C-C line and the end of the floating gate 116 close to the capacitor 120 side is 30 nm.

After the dopant ions are injected into the active region, the formed NMOS capacitor coupling region is adjacent to three borders of the N-gate. The dopant ions at the edge portion of the NMOS capacitor coupling region adjacent to the N-gate boundary undergo rapid thermal annealing, such that thermal side diffusion occurs, and the dopant ions penetrate into the P-well 103 region below the three borders of the N-gate, forming an overlapping region with a width of h between the floating gate 116 and the NMOS capacitor coupling region.

During the programming of the memory cell 100, electrons are injected into the floating gate 116 of the first transistor 110, resulting in a lower threshold voltage of the first transistor 110, making it easier to turn on and causing an increase in the read current during the read operation. For example, the memory cell 100 may be programmed by driving WL to 2v, BL to 2.5v and COM to -2v. At the same time, the N-well 102 and the deep N-well 104 are driven to a potential of 3.3v. In the first transistor 110, the voltage difference between the source 111 and the drain 112 is 4.5v, and the lateral electric field from the source 111 to the drain 112 is much stronger than the longitudinal electric field from the source 111 to the floating gate 116. Therefore, holes are accelerated from one side of the channel 113 (for example, the channel 113 in FIGS. 2-3) to the other side, resulting in collision ionization at the depletion region of the drain 112. The hot electrons generated by the collision ionization are attracted by the positively biased floating gate 116 and injected into the floating gate 116. The negative source 111 bias (-2.0v) attracts most of the hot holes, causing very few hot holes to tunnel into the floating gate 116. Therefore, the number of electrons in the floating gate 116 is greatly increased during programming.

During the erase operation of the memory cell 100, electrons are removed from the floating gate 116 of the first transistor 110, causing the threshold voltage of the first transistor 110 to increase, making it more difficult to turn on, and causing the read current during the read operation to decrease. For example, the memory cell 100 performs an erase operation by driving WL to -4v, BL and COM to 5v. Under this bias condition, the lower plate of the NMOS capacitor 120 forms an inversion layer, and the floating gate 116 is coupled to a potential of approximately -3.5v. When the source 111 and the drain 112 of the first transistor 110 are driven to 5v, an inversion layer is also formed in the channel region of the first transistor 110. The inverted channel connects the source 111 and the drain 112, and receives a 5v voltage. Thus, the total voltage applied to the gate-oxide 115 of the first transistor 110 is about 8.5V, forming a high electric field sufficient to cause the electrons trapped in the floating gate 116 to tunnel to the inversion channel filled with positive carriers. The high electric field may exceed about 10MeV, and the tunneling mechanism is direct tunneling and/or Fowler-Nordheim tunneling. In this operation, the P-well 103 may be driven to a less negative potential value than the substrate 101 bias (0V) because the P-well 103 is separated from the deep N-well 104 by the substrate 101. The N-well 102 and the deep N-well 104 are driven to 5V during erase.

In the read operation, the first transistor 110 in the programmed and erased memory cells 100 has a threshold voltage of approximately 0v and -1.5v, respectively. For example, when the memory cell 100 is in a programmed state, the COM is driven to 1.2v, the BL is pre-charged to 0v, the N-well 102 and the deep N-well 104 are driven to 1.5v, and the WL is driven to 0v. The first transistor 110 of the memory cell 100 is turned on, pulling BL up to 1.2v. The high voltage in BL is then detected by the sense amplifier and driven to output a data signal of state "1".

In practical applications, a plurality of non-volatile memory cells 100 may be put together to form a memory array or a memory.

In the memory array, the WL lines of the memory cells 100 in each row are connected, and the common lines (COM) and bit lines (BL) of the memory cells 100 in each column are connected respectively. The memory array is fabricated in a P-type substrate 101. The deep N-wells 104 of the memory cells 100 are merged to form a single deep N-well. The N-wells 102 and P-wells 103 of the memory cells 100 in a memory row are merged respectively. Thus, each memory row contains one N-well and one P-well. By merging the wells in the same row, the memory cells 100 in the array may be more tightly packaged because most of the space between the wells is eliminated. The memory array is fabricated in the same substrate 101 as other logic circuits on the chip, and the logic circuits require the substrate 101 to connect to ground or be 0v.

The memory cell 100 may further include a second PMOS transistor, which is located in the N-well 102 and connected in series with the first transistor 110. The drain of the second PMOS transistor is connected to the BL word line, and the source of the second PMOS transistor coincides with the drain 112 of the first transistor 110. The source 111 of the first transistor 110 is still connected to the COM line. The gate of the second PMOS transistor is connected to the WL, and the coupling region of the NMOS capacitor is connected to the control gate (CG) signal. During the storage operation, the CG signal is used for controlling the voltage of the floating gate 116.

In the case where the memory cell 100 includes a second PMOS transistor, the operation process and principle of programming, erasing and reading are the same as those of the above case where the second PMOS transistor is not included. That is, the memory cell 100 is programmed by tunneling the hot channel electrons of the first transistor 110 from the channel to the floating gate 116, and the erasing operation is completed by tunneling the electrons from the floating gate 116 of the first transistor 110 into the channel 113 through the F-N mechanism. For example, in the programming operation, programming is performed by driving WL to 0v, BL to 2.5v, CG to 2v and COM to -2v. At the same time, the N-well 102 and the deep N-well 104 are driven to a potential of 2.5v. In the erasing operation, erasing is performed by driving WL to 5v, BL to 3.3v, CG to -4v, COM to 5v, and the N-well 102 and the deep N-well 104 to 5v. In a read operation, when the memory cell 100 is in a programmed state, WL, BL and CG are driven to 0v, COM to 1.2v, and N-well 102 and deep N-well 104 to 1.5v.

In applications, a plurality of memory cells 100 including the second PMOS transistor may also form a memory array or a memory.

In the memory array, the WL and CG lines of the memory cells 100 in the same row are connected respectively, and the common lines and bit lines of the memory cells 100 in the same column are connected respectively. The memory array is fabricated in a P-type substrate 101. The deep N-wells 104 of the memory cells 100 are merged to form a single deep N-well. The N-wells 102 and P-wells 103 of the memory cells 100 in the same memory row are merged respectively. Thus, each memory row contains one N-well and one P-well. By merging the wells in the same row, the memory cells 100 in the array may be more tightly packed because most of the space between the wells is eliminated. The memory array is fabricated in the same substrate 101 as other logic circuits on the chip, and the logic circuits require the substrate 101 to be grounded or at 0v.

This specific embodiment is merely illustrative and not restrictive of the protection scope of the technical solution of the disclosure.

What is claimed is:

1. A non-volatile memory cell, comprising:
a first well and a second well of different types, wherein the first well and the second well are adjacently disposed;
a first transistor, disposed in the first well, wherein the first transistor comprises a floating gate and a gate-oxide of the floating gate; and
a capacitor, disposed in the second well, wherein the capacitor comprises a coupling region disposed in the second well, and the floating gate and the gate-oxide extend from the first well to the second well, forming a gate and a gate-oxide of the capacitor;
wherein the floating gate comprises two electrically different portions, a junction of the two electrically different portions is close to an end of the floating gate, and a distance between the junction and the end is less than 150 nm.

2. The non-volatile memory cell of claim 1, wherein the distance between the junction of the two electrically different portions in the floating gate and the end ranges from 5 nm to 100 nm.

3. The non-volatile memory cell of claim 1, wherein the distance between the junction of the two electrically different portions in the floating gate and the end range from 10 nm to 70 nm.

4. The non-volatile memory cell of claim 1, wherein an end of the floating gate close to the junction of two electrically different portions in the floating gate is close to the capacitor and away from the first transistor.

5. The non-volatile memory cell of claim 4, wherein the first transistor comprises a source and a drain, each of the source and the drain comprises a highly doped region, or the coupling region of the capacitor is a lightly doped region.

6. The non-volatile memory cell of claim 4, wherein the first transistor comprises a source and a drain, each of the source and the drain comprises a highly doped region, and the coupling region of the capacitor is a lightly doped region.

7. The non-volatile memory cell of claim 1, further comprising a second transistor, wherein the second transistor is of the same type as the first transistor, co-located in the first well with the first transistor and connected in series with the first transistor.

8. The non-volatile memory cell of claim 1, wherein the first well is an N-well, the second well is a P-well, the first transistor is a positive channel metal oxide semiconductor (PMOS) transistor, the capacitor is an N-metal-oxide-semiconductor (NMOS) capacitor, and the coupling region of the capacitor in the second well is an N coupling region.

9. A non-volatile memory, comprising:
at least one non-volatile memory cell fabricated on a substrate, wherein the non-volatile memory cell comprises:
a first well and a second well of different types, wherein the first well and the second well are adjacently disposed;
a first transistor, disposed in the first well, wherein the first transistor comprises a floating gate and a gate-oxide of the floating gate; and
a capacitor, disposed in the second well, wherein the capacitor comprises a coupling region disposed in the second well, and the floating gate and the gate-oxide extend from the first well to the second well, forming a gate and a gate-oxide of the capacitor;
wherein the floating gate comprises two electrically different portions, a junction of the two electrically different portions is close to an end of the floating gate, and a distance between the junction and the end is less than 150 nm; and
wherein the substrate comprises a deep well, and the first well and the second well of the non-volatile memory cell are disposed in the deep well.

10. The non-volatile memory of claim 9, wherein the substrate is a P-type substrate, the deep well is a deep N-well, the first well is an N-well, the second well is a P-well, the first transistor is a positive channel metal oxide semiconductor (PMOS) transistor, the capacitor is an N-metal-oxide-semiconductor (NMOS) capacitor, and the coupling region of the capacitor in the second well is an N-coupling region.

11. The non-volatile memory of claim 9, wherein the non-volatile memory is a multi-time programmable and erasable non-volatile memory.

12. The non-volatile memory of claim 9, wherein the distance between the junction of the two electrically different portions in the floating gate and the end ranges from 5 nm to 100 nm.

13. The non-volatile memory of claim 9, wherein the distance between the junction of the two electrically different portions in the floating gate and the end range from 10 nm to 70 nm.

14. The non-volatile memory of claim 9, wherein an end of the floating gate close to the junction of two electrically different portions in the floating gate is close to the capacitor and away from the first transistor.

15. The non-volatile memory of claim 14, wherein the first transistor comprises a source and a drain, each of the source and the drain comprises a highly doped region, or the coupling region of the capacitor is a lightly doped region.

16. The non-volatile memory of claim 14, wherein the first transistor comprises a source and a drain, each of the source and the drain comprises a highly doped region, and the coupling region of the capacitor is a lightly doped region.

17. The non-volatile memory of claim 9, further comprising a second transistor, wherein the second transistor is of the same type as the first transistor, co-located in the first well with the first transistor and connected in series with the first transistor.

18. The non-volatile memory of claim 9, wherein the first well is an N-well, the second well is a P-well, the first transistor is a positive channel metal oxide semiconductor (PMOS) transistor, the capacitor is an N-metal-oxide-semiconductor (NMOS) capacitor, and the coupling region of the capacitor in the second well is an N coupling region.
